(19) United States
(12) Patent Application Publication
(10) Pub. No.: US 2026/0182205 A1
(43) Pub. Date: Jun. 25, 2026

(54) DISPLAY DEVICE

(71) Applicant: LG Display Co., Ltd., Seoul (KR)

(72) Inventors: Jong-Hoon YEO, Paju-si (KR); Jong-Ho KIM, Paju-si (KR); Jun-Ho LEE, Paju-si (KR); Mi-Jin JEONG, Paju-si (KR)

(73) Assignee: LG Display Co., Ltd., Seoul (KR)

(21) Appl. No.: 19/401,032

(22) Filed: Nov. 25, 2025

(30) Foreign Application Priority Data
Dec. 24, 2024 (KR) 10-2024-0195956

(51) Int. Cl. H10K 59/80; H10K 59/122; H10K 59/131; H10K 59/65

(52) U.S. Cl. CPC H10K 59/80521; H10K 59/122; H10K 59/131; H10K 59/65

(57) ABSTRACT

A display device can include a substrate having a display area and a non-display area. The display area includes a first display area and a second display area, and the first display area includes a first pixel region. The second display area includes a second pixel region having a first emission area and a transmissive area. The display device can further include a first light emitting diode in the first pixel region and having a first cathode, a second light emitting diode in the first emission area and having a second cathode, a cathode separation pattern between the first and second pixel regions, a deposition preventing pattern in the transmissive area, and first and second low potential voltage lines in the non-display area. The first and second cathodes are separated by the cathode separation pattern.

### CROSS-REFERENCE TO RELATED APPLICATIONS

The present application claims priority to Korean Patent Application No. 10-2024-0195956, filed in the Republic of Korea on Dec. 24, 2024, the entire contents of which is hereby expressly incorporated by reference into the present application.

### BACKGROUND

### Field

The present disclosure relates to a display device, and more specifically, to a display device being capable of providing high luminance in a sensing pixel region.

### Discussion of the Related Art

As the large-area display device is being developed, the demand for the flat display device with small space occupancy is increasing. As one type of the flat display device, the technology of a liquid crystal display device, an organic light emitting display device including an organic light emitting diode (OLED) and an inorganic light emitting display device including an inorganic light emitting diode is developing rapidly.

For example, in the organic light emitting display device, holes from an anode and electrons from a cathode are combined to generate an exciton in an organic light emitting layer, and the exciton is transformed from an excited state to a ground state. As a result, the light is emitted from the OLED.

### SUMMARY OF THE DISCLOSURE

The present disclosure is directed to a display device that substantially obviates one or more of the problems associated with the limitations and disadvantages of the related art.

An object of the present disclosure is to provide a display device being capable of preventing or minimizing a luminance decrease in a sensing pixel region including an emission area and a transmissive area.

Additional features and advantages of the present disclosure are set forth in the description which follows, and will be apparent from the description, or evident by practice of the present disclosure. The objectives and other advantages of the present disclosure are realized and attained by the features described herein as well as in the appended drawings.

To achieve these and other advantages in accordance with the purpose of the embodiments of the present disclosure, as described herein, an aspect of the present disclosure is a display device comprising a substrate including a display area and a non-display area outside the display area, the display area including a first display area and a second display area, the first display area including a first pixel region, the second display area including a second pixel region including a first emission area and a transmissive area; a first light emitting diode in the first pixel region and including a first anode, a first light emitting layer and a first cathode; a second light emitting diode in the first emission area and including a second anode, a second light emitting layer and a second cathode; a cathode separation pattern between the first pixel region and the second pixel region; a deposition preventing pattern in the transmissive area; a first low patenting voltage line in the non-display area; and a second low potential voltage line in the non-display area, wherein the first cathode and the second cathode are separated by the cathode separation pattern, and wherein the first cathode is connected to the first low potential voltage line, and the second cathode is connected to the second low potential voltage line.

It is to be understood that both the foregoing general description and the following detailed description are example and explanatory and are intended to further explain the present disclosure as claimed.

### BRIEF DESCRIPTION OF THE DRAWINGS

The accompanying drawings, which are included to provide a further understanding of the present disclosure and are incorporated in and constitute a part of this disclosure, illustrate embodiments of the present disclosure and together with the description serve to explain the principles of the present disclosure.

FIG. 1 is a schematic plan view of a display device according to a first embodiment of the present disclosure.

FIG. 2 is a schematic circuit diagram of a pixel region of a display device according to an embodiment of the present disclosure.

FIG. 3 is a schematic cross-sectional view of a pixel region of a display device according to the first embodiment of the present disclosure.

FIG. 4 is a schematic cross-sectional view of an emission pixel region and a sensing pixel region of a display device according to the first embodiment of the present disclosure.

FIG. 5 is a schematic cross-sectional view illustrating a connection of an emission pixel region and a first low potential voltage line and a connection of a sensing pixel region and a second low potential voltage line in a display device according to the first embodiment of the present disclosure.

FIG. 6 is a schematic cross-sectional view illustrating an emission pixel region and a connection of the emission pixel region and a first low potential voltage line in a display device according to the first embodiment of the present disclosure.

FIG. 7 is a schematic plan view of a display device according to a second embodiment of the present disclosure.

FIG. 8 is a schematic cross-sectional view illustrating a connection of an emission pixel region and a first low potential voltage line and a connection of a sensing pixel region and a second low potential voltage line in a display device according to the second embodiment of the present disclosure.

FIG. 9 is a schematic plan view of a display device according to a third embodiment of the present disclosure.

FIG. 10 is a schematic cross-sectional view illustrating a sensing pixel region and a connection of the sensing pixel region and a second low potential voltage line in a display device according to the third embodiment of the present disclosure.

### DETAILED DESCRIPTION OF THE EMBODIMENTS

Reference will now be made in detail to aspects of the present disclosure, examples of which can be illustrated in the accompanying drawings. In the following description, when a detailed description of well-known functions or configurations related to this document is determined to unnecessarily cloud a gist of the inventive concept, the detailed description thereof will be omitted. The progression of processing steps and/or operations described is an example; however, the sequence of steps and/or operations is not limited to that set forth herein and can be changed as is known in the art, with the exception of steps and/or operations necessarily occurring in a particular order. Like reference numerals designate like elements throughout. Names of the respective elements used in the following explanations are selected only for convenience of writing the disclosure and can be thus different from those used in actual products.

Advantages and features of the present disclosure and methods of achieving them will be apparent with reference to the aspects described below in detail with the accompanying drawings. However, the present disclosure is not limited to the aspects disclosed below, but can be realized in a variety of different forms, and only these aspects allow the disclosure of the present disclosure to be complete. The present disclosure is provided to fully inform the scope of the disclosure to the skilled in the art of the present disclosure.

The shapes, sizes, proportions, angles, numbers, and the like disclosed in the drawings for explaining the aspects of the present disclosure are illustrative, and the present disclosure is not limited to the illustrated matters. The same reference numerals refer to the same elements throughout the specification. In addition, in describing the present disclosure, if it is determined that a detailed description of the related known technology unnecessarily obscure the subject matter of the present disclosure, the detailed description thereof can be omitted. When term such as ‘including’, ‘having’, ‘consisting’, and the like are used in this specification, other parts can be added unless ‘only’ is used. When a component is expressed in the singular, cases including the plural are included unless specific statement is described.

The expression such as “at least one of a, b, and c” described throughout the specification can encompass ‘a alone’, ‘b alone’, ‘c alone’, ‘a and b’, ‘a and c’, ‘b and c’, or ‘all of a, b, and c’. The advantages and features of the present invention, and the methods for achieving them, will become apparent by referring to the embodiments described in detail below together with the accompanying drawings.

In construing an element, the element is construed as including an error or tolerance range although there is no explicit description of such an error or tolerance range.

In describing a position relationship, for example, when a position relation between two parts is described as, for example, “on,” “over,” “under,” and “next,” one or more other parts can be disposed between the two parts unless a more limiting term, such as “just” or “direct(ly)” is used.

In describing a time relationship, for example, when the temporal order is described as, for example, “after,” “subsequent,” “next,” and “before,” a case that is not continuous can be included unless a more limiting term, such as “just,” “immediate (ly),” or “direct(ly)” is used.

The area, length, or thickness of each component described in the specification is illustrated for convenience of explanation, and the present invention is not necessarily limited to the area, length and thickness of the illustrated component.

It will be understood that, although the terms such as “first,” “second,” etc. can be used herein to describe various elements, these elements should not be limited by these terms. These terms are only used to distinguish one element from another. For example, a first element could be termed a second element, and, similarly, a second element could be termed a first element, without departing from the scope of the present disclosure.

Features of various aspects of the present disclosure can be partially or overall coupled to or combined with each other, and can be variously inter-operated with each other and driven technically as those skilled in the art can sufficiently understand. The aspects of the present disclosure can be carried out independently from each other, or can be carried out together in co-dependent relationship.

Without specific description, a transistor constituting the pixel circuit of the present disclosure can include at least one of an oxide thin film transistor (Oxide TFT), an amorphous silicon TFT (a-Si TFT), and a low temperature poly silicon (LTPS) TFT.

The following embodiments are described with reference to organic light emitting display devices. However, the embodiment of the present disclosure is not limited to organic light emitting display devices. For example, a display device according to an embodiment of the present disclosure can be an organic light emitting display device using an organic light emitting material or an inorganic light emitting display device using an inorganic light emitting material such as a quantum dot. Namely, the display device of the present disclosure can be an organic light emitting display device or an inorganic light emitting display device.

Reference will now be made in detail to some of the examples and embodiments of the present disclosure, which are illustrated in the accompanying drawings. All components of each display device/apparatus according to all embodiments of the present disclosure are operatively coupled and configured.

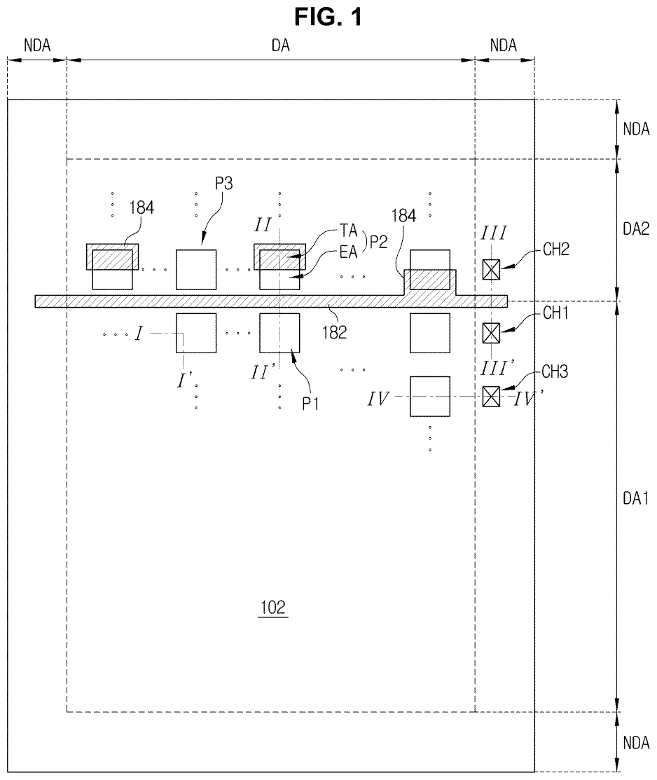

FIG. 1 is a schematic plan view of a display device according to a first embodiment of the present disclosure.

Referring to FIG. 1, the display device according to the first embodiment of the present disclosure includes a substrate 102 and a plurality of pixel regions P1, P2 and P3 arranged on the substrate 102.

A display area DA including a first display area DA1 and a second display area DA2 outside the first display area DA1 and a non-display area NDA outside the display area DA are defined on the substrate 102.

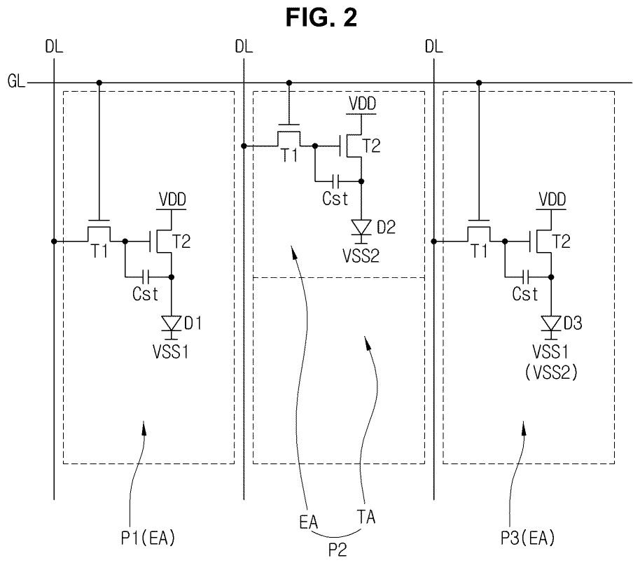

The first pixel region P1 is arranged in the first display area DA. A first light emitting diode D1 (of FIG. 2) is disposed in the first pixel region P1. A plurality of first pixel regions P1 are arranged in the first display area DA1, and the plurality of first pixel regions P1 can include red, green and blue pixel regions.

A second pixel region P2 is arranged in the second display area DA2. A second light emitting diode D2 (of FIG. 2) is disposed in the second pixel region P2. The second pixel region P2 can be one of red, green and blue pixel regions. A plurality of second pixel regions P2 are arranged in the second display area DA2, and the plurality of second pixel regions P1 can include red, green and blue pixel regions.

The second pixel region P2 includes an emission area EA and a transmissive area TA at a side of the emission area EA, and the first pixel region P1 includes an emission area without a transmissive area. For example, an area (e.g., a planar area) of the emission area of the first pixel region P1 can be substantially same as a summation of an area of the emission area of the second pixel region P2 and an area of the transmissive area of the second pixel region P2.

A cathode separation pattern 182 is disposed between the first and second display areas DA1 and DA2.

A first cathode of the first light emitting diode D1 in the first display area DA1 and a second cathode of the second light emitting diode D2 in the second display area DA2 are separated by the cathode separation pattern 182. Namely, the cathodes in the plurality of the first pixel regions P1 in the first display area DA1 are connected to each other, and the cathodes in the plurality of the second pixel regions P2 in the second display area DA2 are connected to each other.

On the other hand, the first cathode of the first pixel region P1 and the second cathode in the second pixel region P2 are separated by the cathode separation pattern 182.

In addition, in the second pixel region P2, the second light emitting diode D2 is disposed in the emission area EA, and a deposition preventing pattern 184 is disposed in the transmissive area TA. Namely, in the second pixel region P2, the second cathode is disposed in the emission area EA, and the deposition preventing pattern 184 without the second cathode is disposed in the transmissive area TA.

The cathode separation pattern 182 can extend along a direction, and the deposition preventing pattern 184 can extend (or protrude) from the cathode separation pattern 182 toward the second pixel region P2.

Accordingly, an area of the first light emitting diode in the first pixel region P1 can be greater than an area of the second light emitting diode in the second pixel region P2.

The first pixel region P1 can be a pixel region providing an image, and second pixel region P2 can be a pixel region providing a sensing function. For example, the first pixel region P1 can be referred to as an emission pixel region, and the second pixel region P2 can be referred to as a sensing pixel region. A sensor can be disposed in the transmissive area.

A third pixel region P3 can be further arranged in the second display area DA2. A third light emitting diode D3 (of FIG. 2) is disposed in the third pixel region P3.

The third pixel region P3 can be the emission pixel region or the sensing pixel region. A plurality of third pixel regions P3 can be arranged in the second display region DA2, and the plurality of third pixel regions P3 can include red, green and blue pixel regions. For convenience of explanation, the display device with the third pixel region P3 being the emission pixel region is illustrated.

A plurality of emission pixel regions are arranged in the first display area DA1, and a plurality of sensing pixel regions or a plurality of sensing pixel regions and a plurality of emission pixel regions are arranged in the second display area DA2.

FIG. 2 is a schematic circuit diagram of a pixel region of a display device according to an embodiment of the present disclosure.

Referring to FIG. 2, the display device includes the first pixel region P1 in the first display area DA1 (of FIG. 1) and the second and third pixel regions P2 and P3 in the second display area DA2 (of FIG. 1).

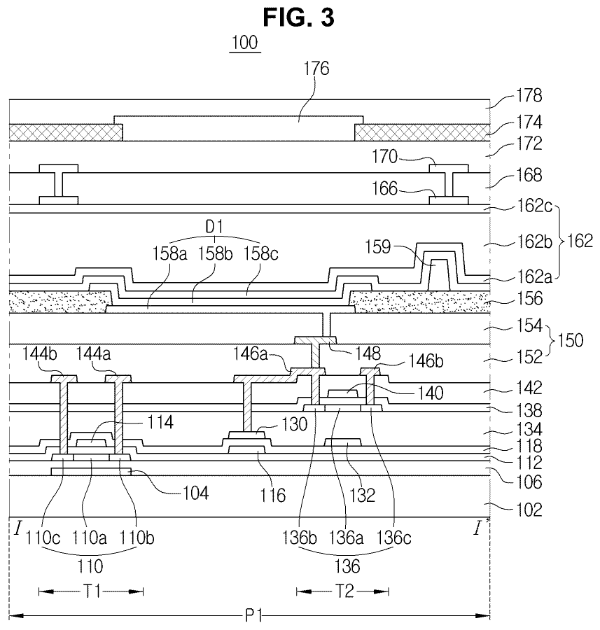

The first pixel region P1 is the emission pixel region, and the second pixel region P2 is the sensing pixel region. The third pixel region P3 is the emission pixel region or the sensing pixel region. In FIG. 3, the third pixel region P3 is the emission pixel region. Namely, in the second display area DA2, the emission pixel region and the sensing pixel region are arranged.

The display device includes a gate line GL and a data line DL crossing each other to define the first, second and third pixel regions P1, P2 and P3. The first and third pixel regions P1 and P3 include the emission area EA, and the second pixel region P2 includes the emission area EA and the transmissive area TA.

In the emission area EA of each of the first to third pixel regions P1, P2 and P3, a first thin film transistor (TFT) T1, a second TFT T2 and a storage capacitor Cst are disposed. In addition, the first, second and third light emitting diodes D1, D2 and D3 are disposed in the first, second and third pixel regions P1, P2 and P3, respectively.

The gate line GL extends along a first direction, and the data line DL extends along a second direction being perpendicular to the first direction. In FIG. 2, the first to third pixel regions P1, P2 and P3 share the gate line GL. In an embodiment of the present disclosure, the first to third pixel regions P1, P2, and P3 can be connected to different gate lines GL.

In the first TFT T1, a gate electrode is connected to the gate line, and a source electrode is connected to the data line DL. In the second TFT T2, a gate electrode is connected to a drain electrode of the first TFT T1, and a source electrode is connected to a high potential voltage VDD.

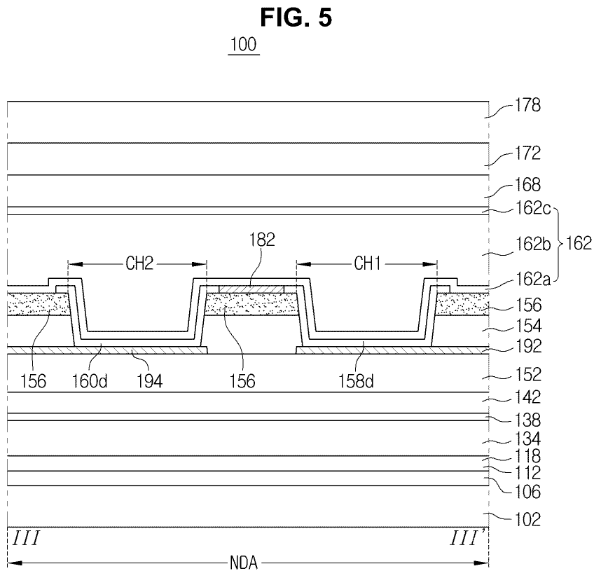

In each of the first to third light emitting diodes D1, D2 and D3, an anode is connected to a drain electrode of the second TFT T2. A cathode of each of the first and third light emitting diodes D1 and D3 is connected to a first low potential voltage line 192 (of FIG. 5) to receive a first low potential voltage, and a cathode of the second light emitting dido D2 is connected to a second low potential voltage line 194 (of FIG. 5) to receive a second low potential voltage.

The storage capacitor Cst is connected to the gate electrode and the drain electrode of the second TFT T2.

In the display device of the present disclosure, the first TFT T1 can be a switching TFT, and the second TFT T2 can be a driving TFT.

In the display device, when the first TFT T1 is turned on by a gate signal applied through the gate line GL, a data signal from the data line DL is applied to the gate electrode of the second TFT T2 and an electrode of the storage capacitor Cst through the first TFT T1.

When the second TFT T2 is turned on by the data signal, an electric current of the high potential voltage is supplied to each of the first, second and third light emitting diodes D1, D2 and D3. As a result, the first, second and third light emitting diodes D1, D2 and D3 emit light.

Accordingly, the current to the first, second and third light emitting diodes D1, D2 and D3 is controlled so that an image can be displayed. Each of the first, second and third light emitting diodes D1, D2 and D3 emits light by the current of the high potential voltage VDD applied through the second TFT T2.

The storage capacitor Cst serves to maintain the voltage of the gate electrode of the driving TFT (the second TFT T2) when the switching TFT (the first TFT T1) is turned off. Accordingly, even if the switching TFT is turned off, a level of an electric current applied from the power line PL to the OLED D is maintained to next frame.

As a result, the display device can display a desired image.

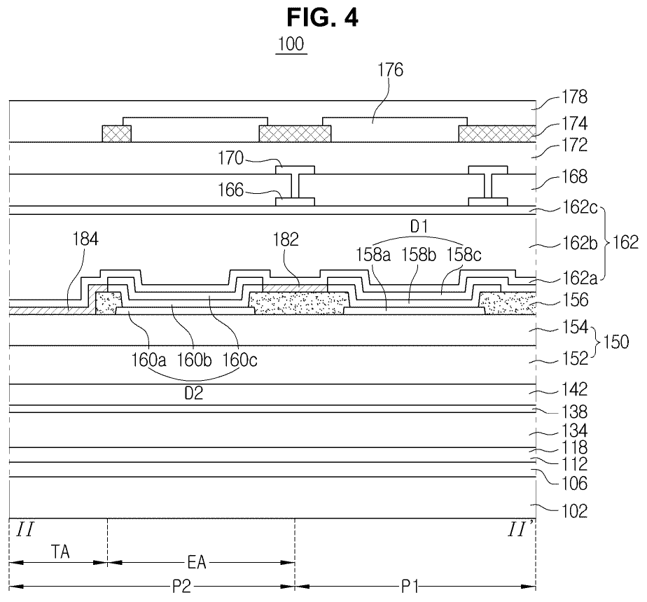

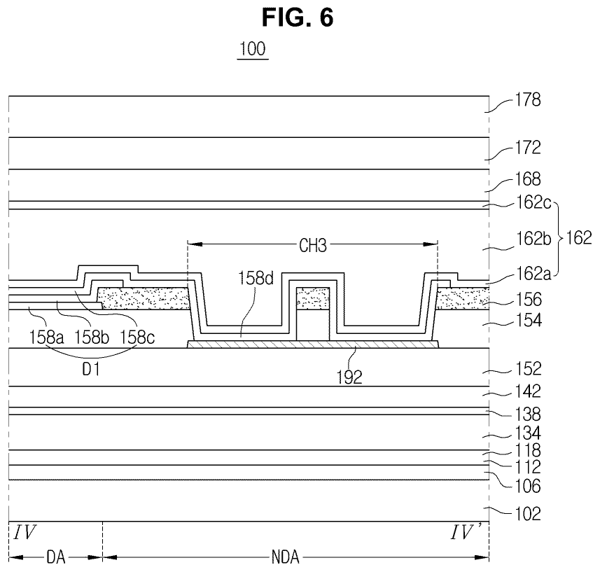

FIG. 3 is a schematic cross-sectional view of a pixel region of a display device according to the first embodiment of the present disclosure, and FIG. 4 is a schematic cross-sectional view of an emission pixel region and a sensing pixel region of a display device according to the first embodiment of the present disclosure. FIG. 5 is a schematic cross-sectional view illustrating a connection of an emission pixel region and a first low potential voltage line and a connection of a sensing pixel region and a second low potential voltage line in a display device according to the first embodiment of the present disclosure, and FIG. 6 is a schematic cross-sectional view illustrating an emission pixel region and a connection of the emission pixel region and a first low potential voltage line in a display device according to the first embodiment of the present disclosure.

FIG. 3 is a cross-sectional view taken along the line I-I′ in FIG. 1, and FIG. 4 is a cross-sectional view taken along the line II-II′ in FIG. 1. FIG. 5 is a cross-sectional view taken along the line III-III′ in FIG. 1, and FIG. 6 is a cross-sectional view taken along the line IV-IV′ in FIG. 1.

Referring to FIGS. 3 to 6 with FIG. 1, the display device 100 according to the first embodiment of the present disclosure includes a substrate 102 including the display area DA, which includes the first display area DA1 and the second display area DA2, and the non-display area NDA outside the display area DA, the first light emitting diode D1 in the first display area DA1, the second light emitting diode D2 in the second display area DA2, the cathode separation pattern 182 disposed between the first and second display areas DA1 and DA2, the deposition preventing pattern 184 disposed in a portion of the second display area DA2, and the first and second low potential voltage lines 192 and 194 in the non-display area NDA.

The first pixel region P1 including the second emission area is arranged in the first display area DA1, and the second pixel region P2 including the first emission area and the transmissive area TA is arranged in the second display area DA2.

The first light emitting diode D1 is disposed in the first pixel region P1 and includes a first anode 158a, a first light emitting layer 158b and a first cathode 158c. The second light emitting diode D2 is disposed in the first emission area of the second pixel region P2 and includes a second anode 160a, a second light emitting layer 160b and a second cathode 160c.

The substrate 102 can be a glass substrate or a plastic substrate. For example, the substrate 102 can be one of polyimide (PI) substrate, polyethersulfone (PES) substrate, polyethylenenaphthalate (PEN) substrate, polyethylene terephthalate (PET) substrate and polycarbonate (PC) substrate.

In an example embodiment of the present disclosure, the substrate 102 can have a triple-layered structure including a first polyimide layer, a second polyimide layer and an interlayer inorganic layer between the first and second polyimide layers. The interlayer inorganic layer can be formed of an inorganic insulating material, e.g., silicon oxide or silicon nitride.

A first light shielding pattern 104 is disposed on the substrate 102. The light through the substrate 104 can be blocked by the first light shielding pattern 104. For example, the first light shielding pattern 104 can be formed of a metallic material, e.g., molybdenum (Mo), aluminum (Al), chromium (Cr), gold (Au), titanium (Ti), nickel (Ni), neodymium (Nd), copper (Cu) or their alloy, and have a single-layered structure or a multi-layered structure.

A buffer layer, which is formed of an inorganic insulating material, e.g., silicon oxide or silicon nitride, can be disposed between the substrate 102 and the first light shielding pattern 104.

A first buffer layer 106 covering the first light shielding pattern 104 is disposed over the substrate 102. The moisture and/or oxygen can be blocked by the first buffer layer 106. For example, the first buffer layer 106 can be formed of an inorganic insulating material, e.g., silicon oxide or silicon nitride, and have a single-layered structure or a multi-layered structure. When the first light shielding pattern 104 is omitted, the first buffer layer 106 can be directly formed on the substrate 102 and contact the substrate 102.

A first semiconductor layer 110 corresponding to the first light shielding pattern 104 is disposed on the first buffer layer 106. The first semiconductor layer 110 can include one of a poly-semiconductor material, an amorphous semiconductor material and an oxide semiconductor material. When the first light shielding pattern 104 and the first buffer layer 106 are omitted, the first semiconductor layer 110 can be directly disposed on the substrate 102.

In an example embodiment of the present disclosure, the first semiconductor layer 110 can be formed of a poly-semiconductor material, e.g., polycrystalline silicon. The first semiconductor layer 110 can include a first channel region 110a, a first source region 110b at one side of the first channel region 110a and a first drain region 110c at the other side of the first channel region 110a. Impurities can be dopped into the first source and drain regions 110b and 110c.

A first gate insulating layer 112 covering the first semiconductor layer 110 is disposed over the first buffer layer 106. The first gate insulating layer 112 can be formed of an inorganic insulating material, e.g., silicon oxide or silicon nitride, and have a single-layered structure or a multi-layered structure.

A first gate electrode 114 corresponding to the first channel region 110a of the first semiconductor layer 110 is disposed on the first gate insulating layer 112. In addition, a first capacitor electrode 116, which is spaced apart from the first gate electrode 114, is disposed on the first gate insulating layer 112.

The first gate electrode 114 and the first capacitor electrode 116 can be disposed on the same layer and be formed of the same material. For example, each of the first gate electrode 114 and the first capacitor electrode 116 can be formed of a metallic material, e.g., Mo, Al, Cr, Au, Ti, Ni, Nd, Cu or their alloy, and have a single-layered structure or a multi-layered structure.

A first interlayer insulating layer 118 covering the first gate electrode 114 and the first capacitor electrode 116 is disposed on the first gate insulating layer 112. The first interlayer insulating layer 118 can be formed of an inorganic insulating material, e.g., silicon oxide or silicon nitride, and have a single-layered structure or a multi-layered structure.

A second capacitor electrode 130 corresponding to the first capacitor electrode 116 and a second light shielding pattern 132 spaced apart from the second capacitor electrode 130 are disposed on the first interlayer insulating layer 118.

The second capacitor electrode 130 and the second light shielding pattern 132 can be disposed on the same layer and be formed of the same material. For example, each of the second capacitor electrode 130 and the second light shielding pattern 132 can be formed of a metallic material, e.g., Mo, Al, Cr, Au, Ti, Ni, Nd, Cu or their alloy, and have a single-layered structure or a multi-layered structure.

A second interlayer insulating layer 134 covering the second capacitor electrode 130 and the second light shielding pattern 132 is disposed on the first interlayer insulating layer 118. The external moisture and/or oxygen can be blocked by the second interlayer insulating layer 134. For example, the second interlayer insulating layer 134 can be formed of an inorganic insulating material, e.g., silicon oxide or silicon nitride, or an organic insulating material, e.g., photo-acryl or benzocyclobutene (BCB), and have a single-layered structure or a multi-layered structure.

A second semiconductor layer 136 corresponding to the second light shielding pattern 132 is disposed on the second interlayer insulating layer 134. The second semiconductor layer 136 can include one of a poly-semiconductor material, an amorphous semiconductor material and an oxide semiconductor material.

In an example embodiment of the present disclosure, the second semiconductor layer 136 can be formed of an oxide semiconductor material, e.g., indium-gallium-zinc oxide (IGZO), zinc oxide (ZnO), tin oxide (SnO₂), copper oxide (Cu₂O), nickel oxide (NiO), indium-tin-zinc oxide (ITZO) or indium-aluminum-zinc oxide (IAZO). The second semiconductor layer 136 can include a second channel region 136a, a second source region 136b at one side of the second channel region 136a and a second drain region 136c at the other side of the second channel region 136a. Impurities can be dopped into the second source and drain regions 136b and 136c.

A second gate insulating layer 138 covering the second semiconductor layer 136 is disposed over the second interlayer insulating layer 134. The second gate insulating layer 138 can be formed of an inorganic insulating material, e.g., silicon oxide or silicon nitride, and have a single-layered structure or a multi-layered structure.

A second gate electrode 140 corresponding to the second channel region 136a of the second semiconductor layer 136 is disposed on the second gate insulating layer 136. For example, the second gate electrode 140 can be formed of a metallic material, e.g., Mo, Al, Cr, Au, Ti, Ni, Nd, Cu or their alloy, and have a single-layered structure or a multi-layered structure.

A third interlayer insulating layer 142 covering the second gate electrode 140 is disposed on the second gate insulating layer 138. The third interlayer insulating layer 142 can be formed of an inorganic insulating material, e.g., silicon oxide or silicon nitride, and have a single-layered structure or a multi-layered structure.

A first source electrode 144a, a first drain electrode 144b, a second source electrode 146a and a second drain electrode 146b are disposed on the third interlayer insulating layer 142.

The first source electrode 144a and the first drain electrode 144b are respectively connected to the first source region 110b and the first drain region 110c via contact holes through the third interlayer insulating layer 142, the second gate insulating layer 138, the second interlayer insulating layer 134, the first interlayer insulating layer 118 and the first gate insulating layer 112. The first source electrode 144a is connected to the first capacitor electrode 116 via a contact hole through the third interlayer insulating layer 142, the second gate insulating layer 138, the second interlayer insulating layer 134 and the first interlayer insulating layer 118.

The second source electrode 146a and the second drain electrode 146b are respectively connected to the second source region 136b and the second drain region 136c via contact holes through the third interlayer insulating layer 142 and the second gate insulating layer 138. The second source electrode 146a is connected to the second capacitor electrode 130 via a contact hole through the third interlayer insulating layer 142, the second gate insulating layer 138 and the second interlayer insulating layer 134.

The first source and drain electrodes 144a and 144b and the second source and drain electrodes 146a and 146b can be disposed on the same layer and formed of the same material. For example, each of the first source and drain electrodes 144a and 144b and the second source and drain electrodes 146a and 146b can be formed of a metallic material, e.g., Mo, Al, Cr, Au, Ti, Ni, Nd, Cu or their alloy, and have a single-layered structure or a multi-layered structure.

The first semiconductor layer 110, the first gate electrode 114, the first source electrode 144a and the first drain electrode 144b constitute a first TFT T1, and the second semiconductor layer 136, the second gate electrode 140, the second source electrode 146a and the second drain electrode 146b constitute a second TFT T2. For example, the first TFT T1 can be a switching TFT, and the second TFT can be a driving TFT. In addition, the first and second capacitor electrodes 116 and 130 constitute a storage capacitor.

The display device 100 of the present disclosure includes the first and second TFTs T1 and T2. Each of the first semiconductor layer 110 of the first TFT T1 and the second semiconductor layer 136 of the second TFT T2 can include one of a poly-semiconductor material, an amorphous semiconductor material and an oxide semiconductor material, and at least one of the first semiconductor layer 110 of the first TFT T1 and the second semiconductor layer 136 of the second TFT T2 can include the oxide semiconductor material. In an example embodiment of the present disclosure, the first semiconductor layer 110 of the first TFT T1 can be formed of the poly-semiconductor material, e.g., polycrystalline silicon, and the second semiconductor layer 136 of the second TFT T2 can be formed of the oxide semiconductor material.

In FIG. 3, the first gate electrode 114, the first source electrode 144a and first drain electrode 146a are disposed over the first semiconductor layer 110, and the second gate electrode 140, the second source electrode 146a and the second drain electrode 146b are disposed over the second semiconductor layer 136. Namely, each of the first and second TFTs T1 and T2 has a coplanar structure. Alternatively, in each of the first and second TFTs T1 and T1, a gate electrode can be disposed under a semiconductor layer, and a source and a drain electrode can be disposed over the semiconductor layer. Namely, each of the TFTs T1 and T2 can have an inverted-staggered structure.

A third TFT, which can be a switching TFT, and a fourth TFT, which can be a driving TFT, are disposed in the second pixel region P2. For example, the third TFT can include a third semiconductor layer, a third gate electrode, a third source electrode and a third drain electrode and can have the same structure as the first TFT T1. The fourth TFT can include a fourth semiconductor layer, a fourth gate electrode, a fourth source electrode and a fourth drain electrode and can have the same structure as the second TFT T2.

In the third pixel region P3 being the emission pixel region, the first TFT T1 as a switching TFT and the second TFT T2 as a driving TFT are disposed the same as the first pixel region P1.

A planarization layer 150 covering the first source and drain electrodes 144a and 144b and the second source and drain electrodes 146a and 146b is disposed on the third interlayer insulating layer 142. The planarization layer 150 can be formed of an organic insulating material, e.g., photo-acryl or BCB.

The planarization layer 150 can include a first planarization layer 152 on the first source and drain electrodes 144a and 144b and the second source and drain electrodes 146a and 146b and a second planarization layer 154 on the first planarization layer 152.

A first connection electrode 148 corresponding to the second source electrode 146a is disposed on the first planarization layer 152. The first connection electrode 148 can be connected to the second source electrode 146a through a contact hole in the first planarization layer 152.

A second connection electrode corresponding to the fourth source electrode is disposed on the first planarization layer 152. The second connection electrode can be connected to the fourth source electrode through a contact hole in the first planarization layer 152.

In addition, the first and second low potential voltage lines 192 and 194 are disposed on the first planarization layer 150a. The first and second low potential voltage lines 192 and 194 are disposed in the non-display area NDA and are spaced apart from each other.

For example, each of the first connection electrode 148, the second connection electrode and the first and second low potential voltage lines 192 and 194 can be formed of a metallic material, e.g., Mo, Al, Cr, Au, Ti, Ni, Nd, Cu or their alloy, and have a single-layered structure or a multi-layered structure.

The second planarization layer 154 is disposed on the first planarization layer 152 to cover the first connection electrode 148, the second connection electrode and the first and second low potential voltage lines 192 and 194. The second planarization layer 154 includes a first connection contact hole exposing the first connection electrode 148, a second connection contact hole exposing the second connection electrode, first and third contact holes CH1 and CH3 exposing the first low potential voltage line 192 and a second contact hole CH2 exposing the second low potential voltage line 194.

In FIG. 1, the first and third contact holes CH1 and CH3 exposing the first low potential voltage line 192 are spaced apart from each other. In an embodiment of the present disclosure, the first and third contact holes CH1 and CH3 can be integrated as one-body.

A first anode 158a and a second anode 160a are disposed on the second planarization layer 154. The first anode 158a corresponds to the first connection electrode 148 and is connected to the first connection electrode 148 through the first connection contact hole in the second planarization layer 154. The second anode 160a corresponds to the second connection electrode and is connected to the second connection electrode through the second connection contact hole in the second planarization layer 154.

The first anode 158a is separately formed in each first pixel region P1, and the second anode 160a is separately formed in each second pixel region P2. Each of the first and second anodes 158a and 160a can include a transparent conductive oxide (TCO) layer, which is formed of a conductive material, e.g., a transparent conductive oxide material, having a relatively high work function. Each of the first and second anodes 158a and 160a can further include a reflective layer. For example, the transparent conductive oxide material can include at least one of indium-tin-oxide (ITO), indium-zinc-oxide (IZO), indium-tin-zinc oxide (ITZO), tin oxide (SnO₂), zinc oxide (ZnO), indium-copper-oxide (ICO) and aluminum-zinc-oxide (Al: ZnO, AZO), and the reflective layer can include at least one of silver (Ag), an alloy of Ag and one of palladium (Pd), Cu, In and Nd and aluminum-palladium-copper alloy (APC).

In an embodiment of the present disclosure, each of the first and second anodes 158a and 160a can have a double-layered structure of Ag/ITO or APC/ITO or a triple-layered structure of ITO/Ag/ITO or ITO/APC/ITO.

A bank 156 is formed on the second planarization layer 154 at a boundary of the pixel region. The bank 156 covers an edge of each of the first and second anodes 158a and 160a and has an opening to respectively expose a center of each of the first and second anodes 158a and 160a. The bank 156 can further include an opening in correspondence to the transmissive area TA of the second pixel region P2.

In the first and third pixel regions P1 and P3, the first anode 158a and the third anode are exposed through the opening of the bank 156. The second anode 160a in the emission area EA of the second pixel region P2 is exposed through the opening of the bank 156, and the second planarization layer 154 in the transmissive area TA is exposed through the opening of the bank 156.

The bank 156 can extend into a portion of the non-display area NDA. The bank 156 can be formed of a transparent organic insulating material, e.g., photo-acryl, benzocyclobutene or polyimide, to be transparent. In an embodiment of the present disclosure, the bank 156 can further include a light-absorbing particle, e.g., a black particle, to have a light-absorbing property.

In the non-display area NDA, the bank 156 is partially removed to expose the first, second and third contact holes CH1, CH2 and CH3. In other words, the bank 156 and the second planarization layer 154 corresponding to the first low potential voltage line 192 are removed to form the first and third contact holes CH1 and CH3, and the bank 156 and the second planarization layer 154 corresponding to the second low potential voltage line 194 are removed to form the second contact hole CH2.

In FIG. 6, a portion of the bank 156 and the second planarization layer 154 are disposed in the third contact hole CH3 so that the third contact hole CH3 is divided into two parts by the portion of the bank 156 and the second planarization layer 154. Alternatively, the bank 156 and the second planarization layer 154 in the third contact hole CH3 can be omitted so that there is a single third contact hole CH3.

A spacer 159 is disposed on the bank 156. For example, the spacer 159 can include an organic insulating material, e.g., photo-acryl, benzocyclobutene (BCB) or polyimide and can have a single-layered structure or a multi-layered structure. The spacer 159 can be omitted.

A first light emitting layer 158b is disposed on the first anode 158a, and a second light emitting layer 160b is disposed on the second anode 160a. The first light emitting layer 158b contacts the first anode 158a in the opening of the bank 156, and the second light emitting layer 160b contacts the second anode 160a in the opening of the bank 156. An end of each of the first and second light emitting layers 158b and 160b can be disposed on the bank 156.

For example, each of the first and second light emitting layers 158b and 160b can include an organic emitting material layer including a host and a dopant. Each of the first and second light emitting layers 158b and 160b can further include at least one of a hole injection layer, a hole transporting layer, an electron blocking layer, a hole blocking layer, an electron transporting layer and an electron injection layer to have a multi-layered structure.

In an embodiment of the present disclosure, each of the first and second light emitting layers 158b and 160b can include an inorganic emitting material layer including an inorganic emitting material, e.g., a quantum dot.

The cathode separation pattern 182 corresponding to a space between the first and second display areas DA1 and DA2 is disposed on the bank 156, and the deposition preventing pattern 184 corresponding to the transmissive area TA of the second pixel region P2 is disposed on the second planarization layer 154.

The cathode separation pattern 182 extends into a portion of the non-display area NDA to be positioned between the first and second low potential voltage lines 192 and 194.

Each of the cathode separation pattern 182 and the deposition preventing pattern 184 includes a compound represented by Formula 1.

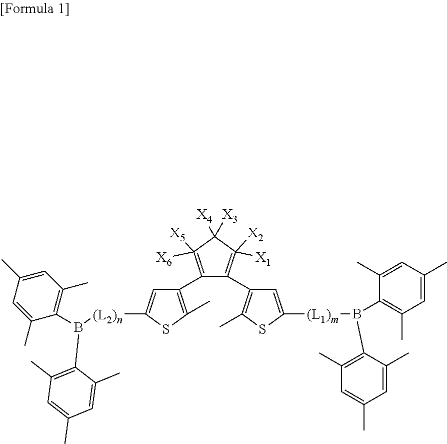

In Formula 1, each of L₁ and L₂ is independently selected from the group consisting of a substituted or unsubstituted C6 to C30 arylene group and a substituted or unsubstituted C3 to C30 heteroarylene group, each of m and n is independently 0 or 1, and each of X₁ to X₆ is independently selected from hydrogen and halogen.

In an embodiment of the present disclosure, a C6 to C30 arylene group can be selected from the group consisting of phenylene, biphenylene, terphenylene, naphthylene, anthracenylene, pentanenylene, indenylene, indenoindenylene, heptalenylene, biphenylenylene, indacenylene, phenanthrenylene, benzophenanthrenylene, dibenzophenanthrenylene, azulenylene, pyrenylene, fluoranthenylene, triphenylenylene, chrysenylene, tetraphenylene, tetrasenylene, picenylene, pentaphenylene, pentacenylene, fluorenylene, indenofluorenylene and spiro-fluorenylene.

In an embodiment of the present disclosure, a C3 to C30 heteroarylene group can be selected from the group consisting of pyrrolylene, pyridinylv, pyrimidinylene, pyrazinylene, pyridazinylene, triazinylene, tetrazinylene, imidazolylene, pyrazolylene, indolylene, isoindolylene, indazolylene, indolizinylene, pyrrolizinylene, carbazolylene, benzocarbazolylene, dibenzocarbazolylene, indolocarbazolylene, indenocarbazolylene, benzofurocarbazolylene, benzothienocarbazolylene, quinolinylene, isoquinolinylene, phthalazinylene, quinoxalinylene, cinnolinylene, quinazolinylene, quinozolinylene, quinolinylene, purinylene, phthalazinylene, quinoxalinylene, benzoquinolinylene, benzoisoquinolinylene, benzoquinazolinylene, benzoquinoxalinylene, acridinylene, phenanthrolinylene, perimidinylene, phenanthridinylene, pteridinylene, cinnolinylene, naphtharidinylene, furanylene, oxazinylene, oxazolylene, oxadiazolylene, triazolylene, dioxynylene, benzofuranyenel, dibenzofuranylene, thiopyranylene, xanthenylene, chromanylene, isochromanylene, thioazinylene, thiophenylene, benzothiophenylene, dibenzothiophenylene, difuropyrazinylene, benzofurodibenzofuranylene, benzothienobenzothiophenylene, benzothienodibenzothiophenylene, benzothienobenzofuranylene, and benzothienodibenzofuranylene.

In an embodiment of the present disclosure, the substituent of a C6 to C30 arylene group and a C3 to C30 heteroarylene group can be selected from the group consisting of a substituted or unsubstituted C1 to C10 alkyl group, a substituted or unsubstituted C3 to C30 cycloalkyl group, a substituted or unsubstituted C6 to C30 aryl group and a substituted or unsubstituted C3 to C30 heteroaryl group.

Halogen can be selected from F, Cl, Br and I.

In an embodiment of the present disclosure, each of m and n can be 0, and each of X₁ to X₆ can be H or F.

In an embodiment of the present disclosure, each of m and n can be 1, each of L₁ and L₂ can be phenylene or thiophenylene, and each of X₁ to X₆ can be H or F.

For example, each of the cathode separation pattern 182 and the deposition preventing pattern 184 independently includes a compound selected from Formula 2.

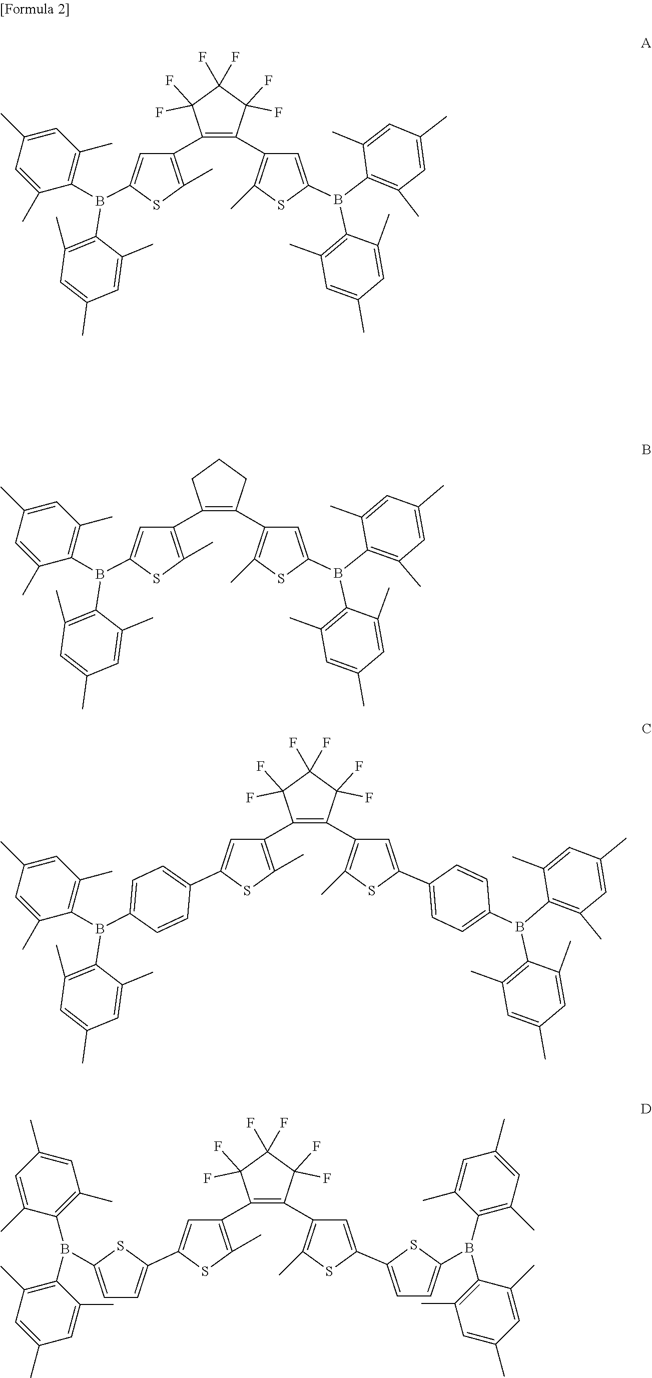

In FIG. 4, the deposition preventing pattern 184 is disposed on the second planarization layer 154 to correspond to the transmissive area TA of the second pixel region P2.

In an embodiment of the present disclosure, the second planarization layer 154 in the transmissive area TA of the second pixel region P2 can be removed, and the deposition preventing pattern 184 can be disposed on the first planarization layer 152. In an embodiment of the present disclosure, the first and second planarization layers 152 and 154 in the transmissive area TA of the second pixel region P2 can be removed, and the deposition preventing pattern 184 can be disposed on the third interlayer insulating layer 142.

In FIG. 4, the second light emitting layer 160b is presented in the emission area EA and is not presented in the transmissive area TA. In an embodiment of the present disclosure, the second light emitting layer 160b can be presented in the emission area EA and the transmissive area TA. In this case, the deposition preventing pattern 184 can be disposed on the second light emitting layer 160b in the transmissive area TA.

The first cathode 158c and the second cathode 160c are formed by depositing a conductive material over the substrate 102 including the first and second light emitting layers 158b and 160b, the cathode separation pattern 182, and the deposition preventing pattern 184. For example, the conductive material can be one of ITO, IZO, Al, Ag, Cu, Pb, Mg, Mo, Ti and their alloy. Each of the first and second cathode 158c and 160c can have a thin thickness to be a transparent electrode or a semi-transparent electrode.

The first cathode 158c is disposed on an entire surface of the first display area DA1. Namely, the first cathodes 158c disposed in the plurality of first pixel regions P1 in the first display area DA1 are connected to each other so that the entire surface of the first display area DA1 is covered by the first cathode 158c.

In addition, the first cathode 158c extends into a portion of the non-display area NDA to contact the first low potential voltage line 192 through the first and third contact holes CH1 and CH3. The extending portion of the first cathode 158c into the non-display area NDA can be referred to as a first cathode extending portion 158d.

The second cathode 160c is disposed in the second display area DA2. The second cathodes 160c disposed in the emission areas EA of the plurality of second pixel regions P2 in the second display area DA2 are connected to each other so that the surface of the second display area DA2 except the transmissive area TA is covered by the second cathode 160c. Namely, in the second pixel region P2, the second cathode 160c is presented in the emission area EA and is not presented in the transmissive area TA. As a result, the deposition preventing pattern 184 is not covered by the second cathode 160c and is exposed.

In addition, the second cathode 160c extends into a portion of the non-display area NDA to contact the second low potential voltage line 194 through the second contact hole CH2. The extending portion of the second cathode 160c into the non-display area NDA can be referred to as a second cathode extending portion 160d.

The metal layer for forming the first and second cathodes 158c and 160c is patterned by the cathode separation pattern 182 and the deposition preventing pattern 184. A metallic material is selectively deposited by the cathode separation pattern 182 and the deposition preventing pattern 184. Namely, when a metallic material is deposited into an entire surface of the display area DA using an open mask, the metallic material is not deposited in an area, where the cathode separation pattern 182 and the deposition preventing pattern 184 are presented, and is deposited in an area, where the cathode separation pattern 182 and the deposition preventing pattern 184 are not presented. As a result, the first and second cathodes 158c and 160c are formed.

In other words, the first cathode 158c in the first display area DA1 and the second cathode 160c in the second display area DA2 are separated by the cathode separation pattern 182, and the metal deposition into the transmissive area TA of the second pixel region P2 is prevented by the deposition preventing pattern 184. Since the compound (e.g., a material) represented by Formula 1 for the deposition preventing pattern 184 is transparent, the transmittance in the transmissive area TA can be maintained.

Since the first and second cathodes 158c and 160c are patterned by the cathode separation pattern 182, a side surface of each of the first and second cathodes 158c and 160c can contact a side surface of the cathode separation pattern 182. In addition, since the first and second cathodes 158c and 160c are patterned by the deposition preventing pattern 184, a side surface of each of the first and second cathodes 158c and 160c can contact a side surface of the deposition preventing pattern 184.

The first anode 158a, the first light emitting layer 158b and the first cathode 158c constitute the first light emitting diode D1, and the second anode 160a, the second light emitting layer 160b and the second cathode 160c constitute the second light emitting diode D2.

In the display device 100 of the present disclosure, the light from the first light emitting layer 158b and the second light emitting layer 160b respectively pass through the first cathode 158c and the second cathode 160c to display an image. Namely, the display device 100 is a top-emission type display device.

The first cathode 158c in the first display area DA1 and the second cathode 160c in the second display area DA2 are separated by the cathode separation pattern 182. The first cathode 158c is electrically connected to the first low potential voltage line 192 through the first cathode extending portion 158d, and the second cathode 160c is electrically connected to the second low potential voltage line 194 through the second cathode extending portion 160d.

In an embodiment of the present disclosure, a first voltage can be applied to the first low potential voltage line 192, and a second voltage, which is smaller than the first voltage, can be applied to the second low potential voltage line 194. Accordingly, the first voltage can be applied to the first cathode 158c through the first cathode extending portion 158d, and the second voltage, which is smaller than the first voltage, can be applied to the second cathode 160c through the second cathode extending portion 160d.

As described above, the emission area without the transmissive area is disposed in the first pixel region P1 as the emission pixel region, and the emission area EA and the transmissive area are disposed in the second pixel region P2 as the sensing pixel region. As a result, the luminance of the light emitted from the second light emitting diode D2 in the second pixel region P2 is lower than the luminance of the light from the first light emitting diode D1 in the first pixel region P1.

However, in the display device 100 of the present disclosure, the first cathode 158c in the first display area DA1 including the first pixel region P1 and the second cathode 160c in the second display area DA2 including the second pixel region P2 are separated by the cathode separation pattern 182, and the first and second cathodes 158c and 160c are connected to the first and second low potential voltage lines 192 and 194, respectively. The relatively low voltage is applied to the second cathode 160c of the second light emitting diode D2 in the second pixel region P2 so that the luminance of the light from the second light emitting diode D2 is increased. Accordingly, the luminance of the first light emitting diode D1 and the luminance of the second light emitting diode D2 can be uniformed, or the luminance difference between the first and second light emitting diodes D1 and D2 can be decreased.

Referring to FIGS. 1 and 5, the first and second low potential voltage lines 192 and 194 are disposed in the non-display area NDA at one side of the display area DA, and the first and second cathode extending portions 158d and 160d extend from the first and second cathodes 158c and 160c along the same direction.

In an embodiment of the present disclosure, the first and second low potential voltage lines 192 and 194 can be disposed in different regions of the non-display area NDA, and the first and second cathode extending portions 158d and 160d extend from the first and second cathodes 158c and 160c along different directions.

For example, the first low potential voltage line 192 can be disposed in the non-display area NDA at one side of the display area DA, and the first cathode extending portion 158d can extend from the first cathode 158c along a first direction to contact the first low potential voltage line 192. The second low potential voltage line 194 can be disposed in the non-display area NDA at the other side of the display area DA, and the second cathode extending portion 160d can extend from the second cathode 160c along a second direction, which is opposite to the first direction, to contact the second low potential voltage line 194.

The first and second low potential voltage lines 192 and 194 are disposed on the same layer, i.e., on the first planarization layer 152, and formed on the same material. In an embodiment of the present disclosure, the first and second low potential voltage lines 192 and 194 can be disposed on different layers. For example, one of the first and second low potential voltage lines 192 and 194 can be disposed on the first planarization layer 152, and the other one of the first and second low potential voltage lines 192 and 194 can be disposed between the substrate 102 and the first planarization layer 152.

An encapsulation layer (or encapsulation film) 162 is disposed over an entire surface of the substrate 102 including the first cathode 158c, the first cathode extending portion 158d, the second cathode 160c, the second cathode extending portion 160d, the cathode separation pattern 182 and the deposition preventing pattern 184 to prevent penetration of moisture. The encapsulation layer 162 includes a first inorganic insulating layer 162a, an organic insulating layer 162b and a second inorganic insulating layer 162c sequentially stacked, but it is not limited thereto.

Each of the first and second inorganic insulating layers 162a and 162c can be formed of an inorganic insulating material, e.g., silicon oxide or silicon nitride. The organic insulating layer 162b can be formed of an organic insulating material, e.g., acryl resin, epoxy resin, phenolic resin, polyamide resin or polyimide resin.

A bridge pattern 166 is disposed on the encapsulation layer 162. The bridge pattern 166 can correspond to a boundary of each of the first to third pixel regions P1, P2 and P3. For example, the bridge pattern 166 can be formed of one of ITO, IZO, Al, Ag, Cu, Pb, Mg, Mo, Ti and their alloy and can have a single-layered structure or a multi-layered structure.

A second buffer layer can be disposed between the encapsulation layer 162 and the bridge pattern 166. For example, the second buffer layer can be formed of an inorganic insulating material, e.g., silicon oxide or silico nitride, and can have a single-layered structure or a multi-layered structure.

A fourth interlayer insulating layer 168 is disposed over an entire surface of the substrate 102 to cover the bridge pattern 166. The fourth interlayer insulating layer 168 can be formed of an inorganic insulating material, e.g., silicon oxide or silico nitride, and can have a single-layered structure or a multi-layered structure.

A touch electrode 170 is disposed on the fourth interlayer insulating layer 168. The touch electrode 170 is connected to the bridge pattern 166 through a contact hole in the fourth interlayer insulating layer 168. For example, the touch electrode 170 can be formed of one of ITO, IZO, Al, Ag, Cu, Pb, Mg, Mo, Ti and their alloy and can have a single-layered structure or a multi-layered structure.

A first protection layer 172 is disposed over an entire surface of the substrate 102 to cover the touch electrode 170. The first protection layer 172 can be formed of an organic insulating material, e.g., photo-acryl or benzocyclobutene, or an inorganic insulating material, e.g., silicon oxide or silico nitride, and can have a single-layered structure or a multi-layered structure.

A black matrix 174 is disposed on the first protection layer 172. The black matrix 174 is positioned at a boundary of the first to third pixel regions P1, P2 and P3 and includes an opening corresponding to the first to third light emitting diodes D1, D2 and D3 and the transmissive area TA of the second pixel region P2. The opening of the black matrix 174 corresponds to the opening of the bank 156.

For the wide viewing angle, a size (e.g., a planar area) of the opening in the black matrix 174 can be greater than that of the opening in the bank 156. Namely, the bank 156 can have a first width, and the black matrix 174 can have a second width, which is smaller than the first width.

The black matrix 174 can be disposed in at least a portion of the non-display area NDA. For example, the black matrix 174 can be disposed to correspond to an entire surface of the non-display area NDA.

A color filter layer 176 corresponding to the black matrix 174 is disposed on the first protection layer 172. The color filter layer 176 can include a red color filter corresponding to the red pixel region, a green color filter corresponding to the green pixel region and a blue color filter corresponding to the blue pixel region.

The color filter layer 176 can include an organic material and a color particle (e.g., a color pigment or a color dye). For example, the organic material can be selected from polymethylmethacrylate, polycarbonate, polyacrylate, polyurethane, epoxy, polyester and polyimide, but it is not limited thereto.

A second protection layer 178 is disposed on the black matrix 174 and the color filter layer 176 and over an entire substrate 102. The second protection layer 178 can be formed of an organic insulating material, e.g., photo-acryl or benzocyclobutene, or an inorganic insulating material, e.g., silicon oxide or silico nitride, and can have a single-layered structure or a multi-layered structure.

In the display device 100 according to the first embodiment of the present disclosure, the cathode separation pattern 182 is disposed between the first display area DA1 including the first pixel region P1 as an emission pixel region and the second display area DA2 including the second pixel region P2 as a sensing pixel region, and the first cathode 158c of the first light emitting diode D1 in the first pixel region P1 and the second cathode 160c of the second light emitting diode D2 in the second pixel region P2 are connected to the first and second low potential voltage lines 192 and 194, respectively. Accordingly, the luminance decrease in the second pixel region P2, which includes the transmissive area TA and the emission area TA to have an emission area being smaller than the first pixel region P1, can be prevented so that the display device 100 can provide high luminance image.

In addition, in the display device 100, the first and second cathodes 158c and 160c are selectively deposited (or formed) in desired areas by using the cathode separation pattern 182 and the deposition preventing pattern 184, which are formed by the same process and of the same material, the display device 100 having a sensing function and high luminance can be provided without additional process.

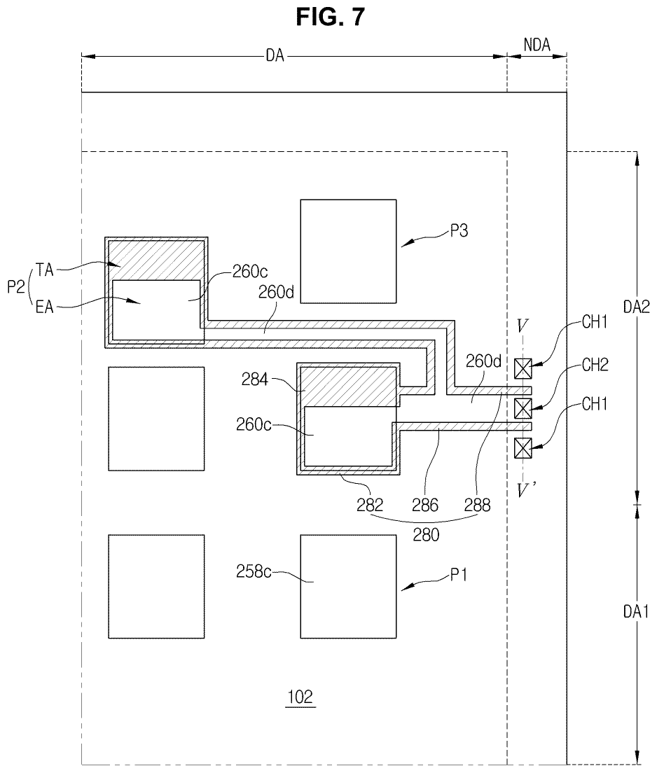

FIG. 7 is a schematic plan view of a display device according to a second embodiment of the present disclosure.

Referring to FIG. 7 with FIG. 2, the display device according to the second embodiment of the present disclosure includes a substrate 102 and a plurality of pixel regions P1, P2 and P3 arranged on the substrate 102.

A display area DA including a first display area DA1 and a second display area DA2 outside the first display area DA1 and a non-display area NDA outside the display area DA are defined on the substrate 102.

The first pixel region P1 is arranged in the first display area DA. A first light emitting diode D1 is disposed in the first pixel region P1.

A second pixel region P2 is arranged in the second display area DA2. A second light emitting diode D2 is disposed in the second pixel region P2. The second pixel region P2 can be one of red, green and blue pixel regions.

The second pixel region P2 includes an emission area EA and a transmissive area TA at a side of the emission area EA, and the first pixel region P1 includes an emission area without a transmissive area. For example, an area (e.g., a planar area) of the emission area of the first pixel region P1 can be substantially same as a summation of an area of the emission area of the second pixel region P2 and an area of the transmissive area of the second pixel region P2.

The first pixel region P1 can be a pixel region providing an image, and second pixel region P2 can be a pixel region providing a sensing function. For example, the first pixel region P1 can be referred to as an emission pixel region, and the second pixel region P2 can be referred to as a sensing pixel region.

A third pixel region P3 can be further arranged in the second display area DA2. A third light emitting diode D3 is disposed in the third pixel region P3.

The third pixel region P3 can be the emission pixel region or the sensing pixel region. A plurality of third pixel regions P3 can be arranged in the second display region DA2, and the plurality of third pixel regions P3 can include red, green and blue pixel regions. For convenience of explanation, the display device with the third pixel region P3 being the emission pixel region is illustrated.

A plurality of emission pixel regions are arranged in the first display area DA1, and a plurality of sensing pixel regions or a plurality of sensing pixel regions and a plurality of emission pixel regions are arranged in the second display area DA2.

A cathode separation pattern 280 for separating the second cathode 260c of the second light emitting diode D2 in the second pixel region P2 from the first cathode 258c of the first light emitting diode D1 in the first pixel region P1 and the third cathode of the third light emitting diode D3 in the third pixel region P3 is disposed in the second display area DA2. The second cathode 260c includes a second cathode extending portion 260d extending into the non-display area NDA. The cathode separation pattern 280 surrounds the second cathode 260c including the second cathode extending portion 260d to separate the second cathode 260c from the first cathode 258c and the third cathode.

The cathode separation pattern 280 can include a first pattern 282 surrounding the second cathode 260c and second and third patterns 286 and 288 respectively extending from the first pattern 282 along both sides of the second cathode extending portion 260d.

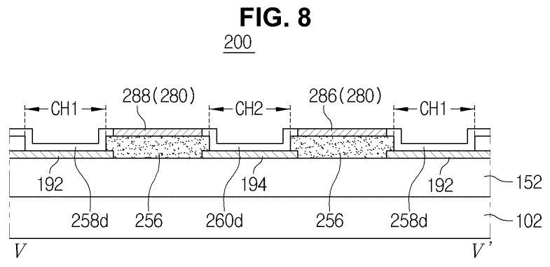

In each of the first to third light emitting diodes D1, D2 and D3, the anode is connected to the drain electrode of the driving TFT T2. Each of the cathode 258c of the first light emitting diode D1 and the cathode of the third light emitting diode D3 is connected to the first low potential voltage line 192 (of FIG. 8) to receive a first low potential voltage VSS1, and the cathode 260c of the second light emitting diode D2 is connected to the second low potential voltage line 194 (of FIG. 8) to receive a second low potential voltage VSS2.

In FIG. 7, the cathode separation pattern 280 is disposed to surround the second cathode 260c in the second pixel region P2 and the second cathode extending portion 260d. Alternatively, the cathode separation pattern 280 can further include a pattern being across a space between the first and second display areas DA1 and DA2 to separate the cathode in the first display area DA1 and the cathode in the second display area DA2.

FIG. 8 is a schematic cross-sectional view illustrating a connection of an emission pixel region and a first low potential voltage line and a connection of a sensing pixel region and a second low potential voltage line in a display device according to the second embodiment of the present disclosure. FIG. 8 is a cross-sectional view taken along the line V-V′ in FIG. 7. FIG. 8 show the display device 200 without elements between the substrate 102 and the third interlayer insulating layer 142 and over the light emitting diode.

Particularly, FIG. 8 show the display device 200 without elements between the substrate 102 and the first planarization layer 152 and over the light emitting diode.

Referring to FIG. 8 with FIGS. 2 and 7, the display device 200 according to the second embodiment of the present disclosure includes a substrate 102 including the display area DA, which includes the first display area DA1 and the second display area DA2, and the non-display area NDA outside the display area DA, the first light emitting diode D1 in the first display area DA1, the second light emitting diode D2 in the second display area DA2, a cathode separation pattern 280 disposed between the first and second display areas DA1 and DA2, a deposition preventing pattern 284 disposed in a portion of the second display area DA2, and the first and second low potential voltage lines 192 and 194 in the non-display area NDA.

The display device 200 according to the second embodiment of the present disclosure has a main difference in the cathode separation pattern 280 in comparison to the display device 100 according to the first embodiment of the present disclosure. The explanation to the display device 200 is focused on the cathode separation pattern 280.

The first and second low potential voltage lines 192 and 194 are disposed in the non-display area NDA and on the first planarization layer 152.

The first to third light emitting diodes D1, D2 and D3 are disposed in the display area DA and over the first planarization layer 152, e.g., on the second planarization layer 154.

A bank 256 is disposed between adjacent two of the first to third pixel regions P1, P2 and P3 in the display area DA and between the first and second low potential voltage lines 192 and 194 in the non-display area and on the first planarization layer 152.

In an embodiment of the present disclosure, the first low potential voltage line 192 can include a first line positioned at one side of the second low potential voltage line 194 and a second line positioned at the other one side of the second low potential voltage line 194. In this case, the bank 256 can include a first bank positioned between the first line and the second low potential voltage line 194 and a second bank positioned between the second line and the second low potential voltage line 194.

The bank 256 includes an opening in correspondence to each of the first to third pixel regions P1, P2 and P3. In addition, the bank 256 further includes first and third contact holes CH1 and CH3 respectively exposing first and second lines of the first low potential voltage line 192 and a second contact hole CH2 exposing the second low potential voltage line 194.

The second planarization layer 154 (of FIG. 4) can be disposed between the first planarization layer 152 and the bank 256 in the non-display area NDA. For example, the second planarization layer 154 can have the same shape as the bank 256. Namely, in the non-display area NDA, the first and third contact holes CH1 and CH3 respectively exposing first and second lines of the first low potential voltage line 192 and the second contact hole CH2 exposing the second low potential voltage line 194 can be formed through the bank 256 and the second planarization layer 154.

Each of the first light emitting diode D1 in the first pixel region P1 and the third light emitting diode D3 in the third pixel region P3 includes a first anode 158a (of FIG. 4), a first light emitting layer 158b (of FIG. 4) and a first cathode 258c, and the first cathode 258c includes a first cathode extending portion 258d extending into the non-display area NDA.

The second light emitting diode D2 in the second pixel region P2 includes a second anode 160a (of FIG. 4), a second light emitting layer 160b (of FIG. 4) and a second cathode 260c, and the second cathode 260c includes a second cathode extending portion 260d extending into the non-display area NDA.

The second cathode extending portion 260d is spaced apart from the first cathode extending portion 258d. The second cathode extending portion 260d can be positioned between the first cathode extending portion 258d of the first light emitting diode D1 and the first cathode extending portion 258d of the third light emitting diode D3.

The cathode separation pattern 280 surrounds the second cathode 260c and the second cathode extending portion 260d. The cathode separation pattern 280 includes the first pattern 282 surrounding the second cathode 260c and the second and third patterns 286 and 288 respectively extending from the first pattern 282 along both sides of the second cathode extending portion 260d. Namely, the cathode separation pattern 280 can have substantially the same shape as the second cathode 260c including the second cathode extending portion 260d. In other words, the first pattern 282 can surround three sides of the second cathode 260c or the second pixel region P2 and have an open portion corresponding to the second cathode extending portion 260d, and each of the second and third patterns 286 and 288 extends from the first pattern 282 along the second cathode extending portion 260d.

The first pattern 282 is disposed on the bank 256 and at a boundary of the second pixel region P2, and the second and third patterns 286 and 288 are disposed on the bank 256 and between the first and second low potential voltage lines 192 and 194.

The deposition preventing pattern 284 is disposed in the transmissive area TA of the second pixel region P2. The deposition preventing pattern 284 can extend from the cathode separation pattern 280.

Each of the cathode separation pattern 280 and the deposition preventing pattern 284 can include the compound represented by Formula 1. For example, each of the cathode separation pattern 280 and the deposition preventing pattern 284 can independently include a compound selected from the compounds in Formula 2.

In an embodiment of the present disclosure, when a plurality of second pixel regions P2 are arranged in the second display area DA2, the second cathode extending portion 260d in one of the second pixel regions P2 can be connected to the second cathode extending portion 260d in the other one of the second pixel regions P2.

In an embodiment of the present disclosure, each of the second cathode extending portion 260d in one of the second pixel regions P2 and the second cathode extending portion 260d in the other one of the second pixel regions P2 extends into the non-display area NDA to be connected to the second low potential voltage line 194.

In the display device 200 according to the second embodiment of the present disclosure, the first and second low potential voltage lines 192 and 194 are disposed in the non-display area NDA at one side of the display area DA, and the first and second cathode extending portions 258d and 260d extend from the first and second cathodes 258c and 260c along the same direction.

In an embodiment of the present disclosure, the first and second low potential voltage lines 192 and 194 can be disposed in different regions of the non-display area NDA, and the first and second cathode extending portions 258d and 260d extend from the first and second cathodes 258c and 260c along different directions.

For example, the first low potential voltage line 192 can be disposed in the non-display area NDA at one side of the display area DA, and the first cathode extending portion 258d can extend from the first cathode 258c along a first direction to contact the first low potential voltage line 192. The second low potential voltage line 194 can be disposed in the non-display area NDA at the other side of the display area DA, and the second cathode extending portion 260d can extend from the second cathode 260c along a second direction, which is opposite to the first direction, to contact the second low potential voltage line 194.

In the display device 200 according to the second embodiment of the present disclosure, the cathode separation pattern 280 is disposed between the first pixel region P1 as an emission pixel region and the second pixel region P2 as a sensing pixel region, and the first cathode 258c of the first light emitting diode D1 in the first pixel region P1 and the second cathode 260c of the second light emitting diode D2 in the second pixel region P2 are connected to the first and second low potential voltage lines 192 and 194, respectively. Accordingly, the luminance decrease in the second pixel region P2, which includes the transmissive area TA and the emission area TA to have an emission area being smaller than the first pixel region P1, can be prevented so that the display device 200 can provide high luminance image.

In addition, in the display device 200, the first and second cathodes 258c and 260c are selectively deposited (or formed) in desired areas by using the cathode separation pattern 280 and the deposition preventing pattern 284, which are formed by the same process and of the same material, the display device 200 having a sensing function and high luminance can be provided without additional process.

Moreover, in the display device 200, when the third pixel region P3 as an emission pixel region is arranged in the second display area DA2, the cathode in the third pixel region P3 is separated from the cathode 260c in the second pixel region P2 as a sensing pixel region and is connected to the first low potential voltage line 192. As a result, the luminance non-uniformity in the first and third pixel regions P1 and P3 as the emission pixel region can be prevented.

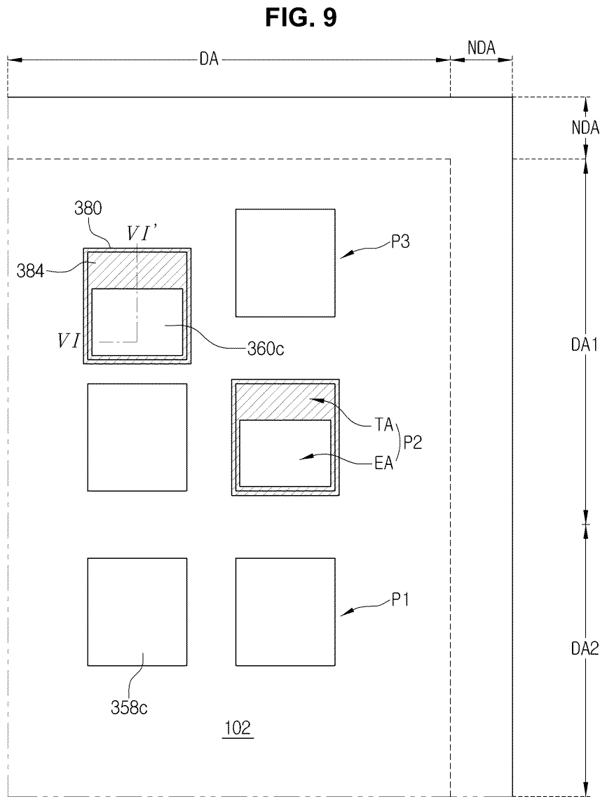

FIG. 9 is a schematic plan view of a display device according to a third embodiment of the present disclosure.

Referring to FIG. 9 with FIG. 2, the display device 300 according to the third embodiment of the present disclosure includes a substrate 102 and a plurality of pixel regions P1, P2 and P3 arranged on the substrate 102.

A display area DA including a first display area DA1 and a second display area DA2 outside the first display area DA1 and a non-display area NDA outside the display area DA are defined on the substrate 102.

The first pixel region P1 is arranged in the first display area DA. A first light emitting diode D1 is disposed in the first pixel region P1.

A second pixel region P2 is arranged in the second display area DA2. A second light emitting diode D2 is disposed in the second pixel region P2. The second pixel region P2 can be one of red, green and blue pixel regions.

The second pixel region P2 includes an emission area EA and a transmissive area TA at a side of the emission area EA, and the first pixel region P1 includes an emission area without a transmissive area. For example, an area (e.g., a planar area) of the emission area of the first pixel region P1 can be substantially same as a summation of an area of the emission area of the second pixel region P2 and an area of the transmissive area of the second pixel region P2.

The first pixel region P1 can be a pixel region providing an image, and second pixel region P2 can be a pixel region providing a sensing function. For example, the first pixel region P1 can be referred to as an emission pixel region, and the second pixel region P2 can be referred to as a sensing pixel region.

A third pixel region P3 can be further arranged in the second display area DA2. A third light emitting diode D3 is disposed in the third pixel region P3.

The third pixel region P3 can be the emission pixel region or the sensing pixel region. A plurality of third pixel regions P3 can be arranged in the second display region DA2, and the plurality of third pixel regions P3 can include red, green and blue pixel regions. For convenience of explanation, the display device with the third pixel region P3 being the emission pixel region is illustrated.

A plurality of emission pixel regions are arranged in the first display area DA1, and a plurality of sensing pixel regions or a plurality of sensing pixel regions and a plurality of emission pixel regions are arranged in the second display area DA2.

A cathode separation pattern 380 for separating the second cathode 360c of the second light emitting diode D2 in the second pixel region P2 from the first cathode 358c of the first light emitting diode D1 in the first pixel region P1 and the third cathode of the third light emitting diode D3 in the third pixel region P3 is disposed in the second display area DA2. The cathode separation pattern 380 surrounds the second cathode 360c to be separated from the first cathode 358c and the third cathode.

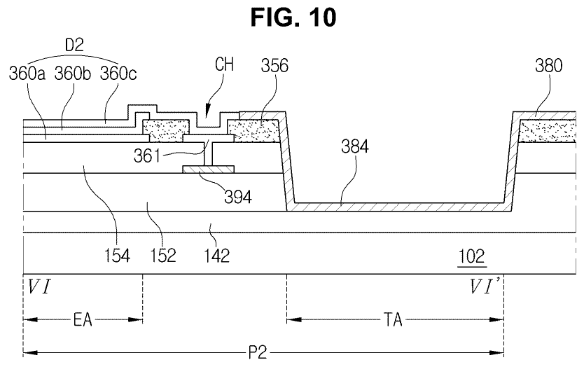

In each of the first to third light emitting diodes D1, D2 and D3, the anode is connected to the drain electrode of the driving TFT T2. Each of the cathode 258c of the first light emitting diode D1 and the cathode of the third light emitting diode D3 is connected to the first low potential voltage line 192 (of FIG. 5) to receive a first low potential voltage VSS1, and the cathode 260c of the second light emitting diode D2 is connected to the second low potential voltage line 394 (of FIG. 10) to receive a second low potential voltage VSS2.

The second low potential voltage line 394 extends into the second pixel region P2, and the second cathode 360c and the second low potential voltage line 394 in the second pixel region P2 are connected to each other. Namely, the cathode separation pattern 380 completely surrounds each second pixel region P2, and the second cathode 360c in the second pixel region P2 is separated from the first cathode 358c in the first pixel region P2 and the third cathode in the third pixel region P3. In addition, the second cathode 360c in one of the second pixel regions P2 is separated from the second cathode 360c in the other one of the second pixel regions P2.

In an embodiment of the present disclosure, the second cathode 360c in one of the second pixel regions P2 the second cathode 360c in the other one of the second pixel regions P2 can be connected to each other.

In FIG. 9, the cathode separation pattern 380 is disposed to surround the second pixel region P2. Alternatively, the cathode separation pattern 380 can further include a pattern being across a space between the first and second display areas DA1 and DA2 to separate the cathode in the first display area DA1 and the cathode in the second display area DA2.

FIG. 10 is a schematic cross-sectional view illustrating a sensing pixel region and a connection of the sensing pixel region and a second low potential voltage line in a display device according to the third embodiment of the present disclosure. FIG. 10 is a cross-sectional view taken along the line VI-VI′ in FIG. 9.

Referring to FIG. 10 with FIGS. 2 and 9, the display device 300 according to the second embodiment of the present disclosure includes a substrate 102 including the display area DA, which includes the first display area DA1 and the second display area DA2, and the non-display area NDA outside the display area DA, the first light emitting diode D1 in the first display area DA1, the second light emitting diode D2 in the second display area DA2, a cathode separation pattern 280 disposed between the first and second display areas DA1 and DA2, a deposition preventing pattern 284 disposed in a portion of the second display area DA2, and the first low potential voltage line 192 (of FIG. 5) and the second low potential voltage line 194 in the non-display area NDA.

The display device 300 according to the third embodiment of the present disclosure has a main difference in the cathode separation pattern 380 in comparison to the display device 100 according to the first embodiment of the present disclosure. The explanation to the display device 300 is focused on the cathode separation pattern 380.

The third interlayer insulating layer 142 is disposed on the substrate 102, and the first planarization layer 152 is disposed on the third interlayer insulating layer 142. The second low potential voltage line 394 is disposed on the first planarization layer 152.

In an embodiment of the present disclosure, the second low potential voltage line 394 can be disposed between the substrate 102 and the first planarization layer 152.

The second planarization layer 154 covering the second low potential voltage line 394 is disposed on the first planarization layer 152. The first and second planarization layers 152 and 154 in the transmissive area TA of the second pixel region P2 can be removed so that the third interlayer insulating layer 142 is exposed.

The second anode 360a corresponding to the emission area EA is disposed on the second planarization layer 154 and in the second pixel region P2. In addition, an auxiliary electrode 361 is disposed on the second planarization layer 154 and between the emission area EA and the transmissive area TA. The auxiliary electrode 361 is connected to the second low potential voltage line 394 through a contact hole in the second planarization layer 154.

The auxiliary electrode 361 can be formed of the same material as the second anode 360a. Alternatively, the auxiliary electrode 361 can be formed of the same material as the second low potential voltage line 394.

The bank 356 is disposed at a boundary of the second pixel region P2 and between the transmissive area TA and the emission area EA. The bank 356 covers an edge of the second anode 360a and includes an opening in correspondence to the transmissive area TA and the emission area EA. The second anode 360a is exposed through the opening in the emission area EA, and the third interlayer insulating layer 142 is exposed through the opening in the transmissive area TA.

In addition, the bank 356 further includes an auxiliary contact hole CH exposing the auxiliary electrode 361.

The second light emitting layer 360b is disposed on the second anode 360a in the emission area EA of the second pixel region P2. The second light emitting layer 360b may not be presented in the transmissive area TA so that the third interlayer insulating layer 142 is exposed.

The cathode separation pattern 380 is disposed to surround the second pixel region P2, and the deposition preventing pattern 384 is disposed in the transmissive area TA of the second pixel region P2. The cathode separation pattern 380 can be positioned on the bank 356 surrounding the second pixel region P2, and the deposition preventing pattern 384 can be positioned on the third interlayer insulating layer 142 in the transmissive area TA.

In an embodiment of the present disclosure, at least one of the first and second planarization layers 152 and 154 can be formed on the third interlayer insulating layer 142 in the transmissive area TA. In this case, the deposition preventing pattern 384 can be positioned on the first planarization layer 152 or the second planarization layer 154 in the transmissive area TA.

In FIG. 10, the second light emitting layer 360b is presented in the emission area EA and is not presented in the transmissive area TA. In an embodiment of the present disclosure, the second light emitting layer 360b can be presented in the emission area EA and the transmissive area TA. In this case, the deposition preventing pattern 384 can be positioned on the second light emitting layer 360b in the transmissive area TA.

Each of the cathode separation pattern 380 and the deposition preventing pattern 384 can include the compound represented by Formula 1. For example, each of the cathode separation pattern 380 and the deposition preventing pattern 384 can independently include a compound selected from the compounds in Formula 2.

The second cathode 360c is disposed on the second light emitting layer 360b in the emission area EA. The second cathode 360c extends into the auxiliary contact hole CH in the bank 356 to be connected to the auxiliary electrode 361 through the auxiliary contact hole CH. Accordingly, the second cathode 360c is electrically connected to the second low potential voltage line 394 through the auxiliary electrode 361.

The first light emitting diode D1 is disposed in the first pixel region P1, and the third light emitting diode D3 is disposed in the third pixel region P3. For example, the first cathode 358c of the first light emitting diode D1 in the first pixel region P1 can extend into the non-display area NDA to be connected to the first low potential voltage line 192 (of FIG. 5). In an embodiment of the present disclosure, the first cathode 358c can be connected to the first low potential voltage line 192 in the first pixel region P1.

In the display device 300 according to the third embodiment of the present disclosure, the cathode separation pattern 380 is disposed between the first pixel region P1 as an emission pixel region and the second pixel region P2 as a sensing pixel region, and the first cathode 358c of the first light emitting diode D1 in the first pixel region P1 and the second cathode 360c of the second light emitting diode D2 in the second pixel region P2 are connected to the first low potential voltage line 192 and the second low potential voltage line 394, respectively. Accordingly, the luminance decrease in the second pixel region P2, which includes the transmissive area TA and the emission area TA to have an emission area being smaller than the first pixel region P1, can be prevented so that the display device 300 can provide high luminance image.

In addition, in the display device 300, the first and second cathodes 358c and 360c are selectively deposited (or formed) in desired areas by using the cathode separation pattern 380 and the deposition preventing pattern 384, which are formed by the same process and of the same material, the display device 300 having a sensing function and high luminance can be provided without additional process.

Moreover, in the display device 300, when the third pixel region P3 as an emission pixel region is arranged in the second display area DA2, the cathode in the third pixel region P3 is separated from the second cathode 360c in the second pixel region P2 as a sensing pixel region and is connected to the first low potential voltage line 192. As a result, the luminance non-uniformity in the first and third pixel regions P1 and P3 as the emission pixel region can be prevented or minimized.

It will be apparent to those skilled in the art that various modifications and variations can be made in the embodiments of the present disclosure without departing from the spirit or scope of the present disclosure. Thus, it is intended that the modifications and variations cover this disclosure provided they come within the scope of the appended claims and their equivalents.

What is claimed is:

1. A display device, comprising:
a substrate including a display area and a non-display area outside the display area, the display area including a first display area and a second display area, the first display area including a first pixel region, the second display area including a second pixel region including a first emission area and a transmissive area;
a first light emitting diode in the first pixel region and including a first anode, a first light emitting layer and a first cathode;
a second light emitting diode in the first emission area and including a second anode, a second light emitting layer and a second cathode;
a cathode separation pattern between the first pixel region and the second pixel region;
a deposition preventing pattern in the transmissive area;
a first low potential voltage line in the non-display area; and
a second low potential voltage line in the non-display area,
wherein the first cathode and the second cathode are separated by the cathode separation pattern, and
wherein the first cathode is connected to the first low potential voltage line, and the second cathode is connected to the second low potential voltage line.

2. The display device according to claim 1, wherein the deposition preventing pattern extends from the cathode separation pattern.

3. The display device according to claim 1, wherein the cathode separation pattern is disposed across a space between the first and second display areas.

4. The display device according to claim 3, wherein the first cathode in the first pixel region and a first cathode in another first pixel region are connected to each other, and
wherein the second cathode in the second pixel region and a second cathode in another second pixel region are connected to each other.

5. The display device according to claim 1, wherein the second cathode includes a cathode extending portion extending into the non-display area to be connected to the second low potential voltage line, and the cathode separation pattern surrounds the second cathode and the cathode extending portion.

6. The display device according to claim 5, wherein the cathode extending portion in the second pixel region is connected to the cathode extending portion in another second pixel region.

7. The display device according to claim 5, wherein the first low potential voltage line includes a first line at one side of the second low potential voltage line and a second line at another side of the second low potential voltage line.

8. The display device according to claim 7, further comprising:
a first bank between the first line and the second low potential voltage line; and
a second bank between the second line and the second low potential voltage line,
wherein the cathode separation pattern is disposed on the first and second banks.

9. The display device according to claim 1, wherein the cathode separation pattern surrounds the second pixel region.

10. The display device according to claim 9, wherein the second cathode is connected to the second low potential voltage line in the second pixel region.

11. The display device according to claim 1, wherein the first pixel region includes a second emission area.

12. The display device according to claim 11, wherein a size of an area of the second emission area is greater than a size of an area of the first emission area.

13. The display device according to claim 12, wherein the size of the area of the second emission area is equal to a size of a summation of the area of the first emission area and an area of the transmissive area.

14. The display device according to claim 1, wherein a size of an area of the first cathode is greater than a size of an area of the second cathode.

15. The display device according to claim 1, wherein the first and second low potential voltage lines are disposed at a same layer.

16. The display device according to claim 1, wherein a first voltage is applied to the first low potential voltage line, and a second voltage is applied to the second low potential voltage line, and
wherein the second voltage is smaller than the first voltage.

17. The display device according to claim 1, further comprising:
a sensor disposed in the transmissive area.

18. The display device according to claim 1, wherein the cathode separation pattern and the deposition preventing pattern include a same material.

19. The display device according to claim 1, wherein a side surface of the cathode separation pattern contacts a side surface of the first cathode and a side surface of the second cathode.

20. The display device according to claim 1, wherein a side surface of the deposition preventing pattern contacts a side surface of the first cathode and a side surface of the second cathode.

21. The display device according to claim 16, wherein the first light emitting diode and the second light emitting diode are configured to generate light at a uniform luminance level.

22. The display device according to claim 1, wherein the second cathode is not disposed in the transmissive area.

23. The display device according to claim 1, wherein the second display area further includes a third pixel region, and a third light emitting diode is disposed in the third pixel region.

24. The display device according to claim 23, wherein a cathode of the third light emitting diodes is connected to the first low potential voltage line.

25. The display device according to claim 5, wherein the cathode separation pattern includes:
a first pattern surrounding three sides of the second cathode and having an open portion corresponding to the cathode extending portion, and
a second pattern and a third pattern respectively extending from the first pattern along both sides of the cathode extending portion.

26. The display device according to claim 7, further comprising:
a bank including first and third contact holes respectively exposing the first and second lines and a second contact hole exposing the second low potential voltage line.

27. The display device according to claim 26, wherein the bank is disposed on a planarization layer, and
wherein a portion of the bank and a portion of the planarization layer are disposed in the third contact hole.

28. The display device according to claim 1, wherein the cathode separation pattern completely surrounds the second pixel region, and
wherein the second low potential voltage line extends into the second pixel region.
